(19) United States
(12) Patent Application Publication
(10) Pub. No.: US 2024/0021973 A1
(43) Pub. Date: Jan. 18, 2024

(54) PATCH ANTENNAS IN PACKAGES

(71) Applicant: TEXAS INSTRUMENTS INCORPORATED, Dallas, TX (US)

(72) Inventors: Harshpreet Singh Phull BAKSHI, Dallas, TX (US); Rajen Manicon MURUGAN, Dallas, TX (US); Sylvester ANKAMAH-KUSI, Dallas, TX (US)

(21) Appl. No.: 18/345,400

(22) Filed: Jun. 30, 2023

Related U.S. Application Data
(60) Provisional application No. 63/390,226, filed on Jul. 18, 2022.

(51) Int. Cl. H01Q 1/22; H01Q 1/48; H01Q 9/04; H01L 23/522; H01L 23/31; H01L 21/56

(52) U.S. Cl. CPC H01Q 1/2283; H01Q 1/48; H01Q 9/0407; H01L 23/5226; H01L 23/3107; H01L 21/56; H01L 2224/48245; H01L 24/48

(57) ABSTRACT

In examples, a semiconductor package comprises a semiconductor substrate including a device side having circuitry formed therein. The package also includes a conductive layer positioned above the semiconductor substrate; a patch antenna coupled to the conductive layer and to the device side of the semiconductor substrate; and a mold compound covering the patch antenna. The mold compound has a relative permittivity ranging from 3.4 to 3.5 and a loss tangent ranging from 0.0025 to 0.013.

### CROSS-REFERENCE TO RELATED APPLICATIONS

The present application claims priority to U.S. Provisional Patent Application No. 63/390,226, which was filed Jul. 18, 2022, is titled “Encapsulated 300-GHz On-Chip Patch Antenna,” and is hereby incorporated herein by reference in its entirety.

### BACKGROUND

Devices that engage in wireless communications may include one or more antennas. Such antennas may be incorporated into wireless devices in a variety of configurations. In some configurations, an antenna may be included on a semiconductor die along with circuitry configured to operate the antenna for wireless communications. Such antennas may be referred to as “on-chip antennas” because they are either on the semiconductor die or because they are co-located in the same semiconductor package as the semiconductor die.

### SUMMARY

In examples, a semiconductor package comprises a semiconductor substrate including a device side having circuitry formed therein. The package also includes a conductive layer positioned above the semiconductor substrate; a patch antenna coupled to the conductive layer and to the device side of the semiconductor substrate; and a mold compound covering the patch antenna. The mold compound has a relative permittivity ranging from 3.4 to 3.5 and a loss tangent ranging from 0.0025 to 0.013.

In examples, a method for manufacturing a semiconductor package comprises coupling a first conductive layer to a semiconductor substrate; coupling a second conductive layer to the first conductive layer using a via, the via extending through an insulative layer between the first and second conductive layers, the second conductive layer farther from the semiconductor substrate than the first conductive layer; forming a cavity in a surface of the second conductive layer facing away from the semiconductor substrate, the cavity having a metal floor and multiple metal walls, the floor and multiple walls coupled to a ground connection of the semiconductor substrate through the via; positioning a patch antenna in the cavity; and covering the patch antenna with a mold compound.

### BRIEF DESCRIPTION OF THE DRAWINGS

FIG. 1A is a perspective view of a patch antenna semiconductor die configured to efficiently radiate wireless signals, in accordance with various examples.

FIG. 1B is a top-down view of a patch antenna semiconductor die configured to efficiently radiate wireless signals, in accordance with various examples.

FIG. 1C is a profile view of a patch antenna semiconductor die configured to efficiently radiate wireless signals, in accordance with various examples.

FIG. 2A is a perspective view of a patch antenna configured to efficiently radiate wireless signals, in accordance with various examples.

FIG. 2B is a top-down view of a patch antenna configured to efficiently radiate wireless signals, in accordance with various examples.

FIG. 3A is a perspective view of a patch antenna semiconductor package configured to efficiently radiate wireless signals, in accordance with various examples.

FIG. 3B is a top-down view of a patch antenna semiconductor package configured to efficiently radiate wireless signals, in accordance with various examples.

FIG. 3C is a profile view of a patch antenna semiconductor package configured to efficiently radiate wireless signals, in accordance with various examples.

FIG. 4 is a graph depicting radiation efficiency as a function of the thickness of a variety of mold compounds in a patch antenna semiconductor package, in accordance with various examples.

FIG. 5A is a perspective view of a patch antenna semiconductor package and the radiation gain patterns of efficiently radiating wireless signals, in accordance with various examples.

FIG. 5B is a first profile view of a patch antenna semiconductor package and the radiation gain patterns of efficiently radiating wireless signals, in accordance with various examples.

FIG. 5C is a second profile view of a patch antenna semiconductor package and the radiation gain patterns of efficiently radiating wireless signals, in accordance with various examples.

FIG. 6 is a 3-d polar plot of the gain of a wireless signal efficiently radiated by a patch antenna semiconductor package, in accordance with various examples.

FIG. 7 is a graph depicting gains and return losses as a function of the frequency of a signal radiated by a patch antenna semiconductor package, in accordance with various examples.

FIG. 8 is a graph depicting radiation efficiency as a function of signal frequency for a range of different relative permittivities of a patch antenna semiconductor package mold compound, in accordance with various examples.

FIG. 9 is a graph depicting radiation efficiency as a function of signal frequency for a range of different loss tangents of a patch antenna semiconductor package mold compound, in accordance with various examples.

FIG. 10 is a profile, cross-sectional view of a patch antenna semiconductor die configured to efficiently radiate wireless signals, in accordance with various examples.

FIG. 11 is a flow diagram of a method for manufacturing a patch antenna semiconductor package, in accordance with various examples.

FIGS. 12A-12J are a process flow of a method for manufacturing a patch antenna semiconductor package, in accordance with various examples.

### DETAILED DESCRIPTION

On-chip antennas suffer from multiple drawbacks that diminish operational radiation efficiency. These drawbacks are particularly problematic in the mmWave range, e.g., in the 30 GHz-300 GHz range. For example, in some configurations of a semiconductor package, an on-chip patch antenna (i.e., an antenna comprising a planar sheet of metal coupled to or positioned adjacent to a ground plane) is positioned an unfavorable distance from a ground plane, and thus this configuration of two metal plates (the antenna and the ground plane) separated by a dielectric exhibits capacitive behavior, tending to store energy rather than radiate the energy. This diminishes operational efficiency. Furthermore, mold compounds used to cover the components of the semiconductor package in which the patch antenna is included have inherent properties that inflict significant dielectric losses on energy to be radiated. Further still, structures adjacent to the patch antenna and to the semiconductor package containing the antenna may reflect or absorb radiated energy, thereby diminishing radiation efficiency. When wireless signals are radiated with poor directionality (i.e., the radiated energy is not focused in a particular direction), the signals are likely to encounter these adjacent structures, which will reduce the total amount of energy that can reach the intended wireless communication target.

This disclosure describes various examples of patch antenna semiconductor packages that mitigate the challenges described above. In particular, example packages include a semiconductor die having a ground structure that extends through the die, from a device (i.e., circuitry) side of the silicon near the bottom of the die to a patch antenna near the top of the die. The ground structure may, for example, comprise four walls, with each wall including a series of metal layers and vias coupled in a chain configuration that extends vertically through the die by coupling to the silicon on one end (e.g., at a ground node of the silicon) and extending to a cavity housing the patch antenna at the other end. Furthermore, in some examples, the cavity at the top of the package may contain the patch antenna and may have a floor and walls covered by, or composed of, a metal that is coupled to the chain of metal layers and vias described above. During operation, the ground structure directs radiated energy vertically and outward, away from the die, and the ground structure prevents energy from being radiated horizontally. In this way, the ground structure facilitates radiation of energy in the desired direction, instead of energy dissipating in the horizontal (lateral) or other, undesirable directions. The ground structure is described as having four walls, but the ground structure may have a different number of walls (e.g., three or five walls).

Further, in examples, semiconductor packages described herein include mold compounds that cover components of the packages, such as the semiconductor die, the patch antenna, etc. The mold compounds have specific properties that are critical to improving radiation efficiency and directionality. For optimal performance, experimental simulation data indicates it is critical that the mold compound of the semiconductor package have a relative permittivity of 2.36 to 3.4 and a loss tangent of 0.013 to 0.0025. The mold compound may have other features that also improve radiation efficiency, such as a thickness (between the patch antenna and the top of the mold compound) of approximately one-fourth of the wavelength of the signal being radiated (a mold compound thickness of one-fourth of the signal wavelength being used because in wave theory, this thickness is conducive to constructive interference and thus radiation efficiency, such as when a wave incident from an antenna traverses a ¼ wavelength mold compound thickness, is reflected back from the medium interface toward the antenna and thus again traverses a ¼ wavelength distance, and combines with waves incident from the antenna). These and other features are now described with reference to the drawings.

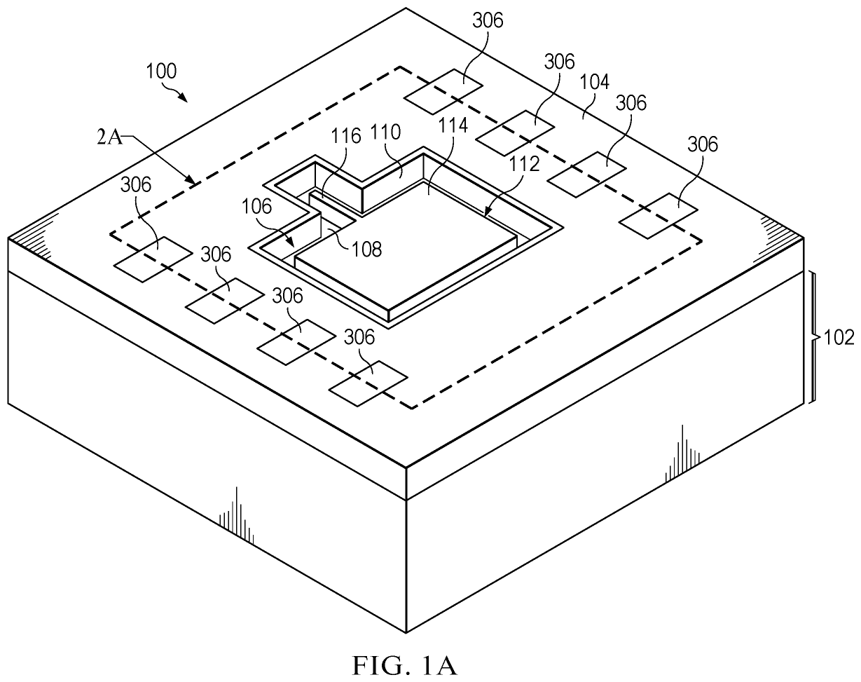

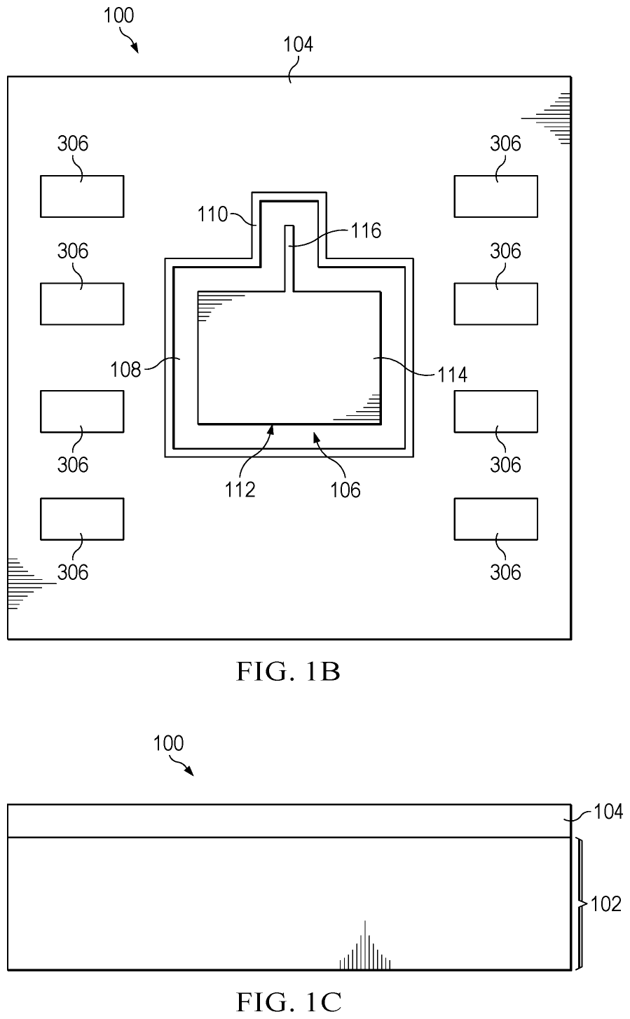

FIG. 1A is a perspective view of a patch antenna semiconductor die 100 configured to efficiently radiate wireless signals, in accordance with various examples. The die 100 may be included as part of a semiconductor package, described below. The die 100 includes a portion 102 and a portion 104. In examples, the portion 104 is part of the portion 102 but is shown as a separate component to facilitate understanding. The portion 102 may include various components, such as a silicon substrate that includes a device side in which circuitry is formed. The portion 102 may also include a back end of line (BEOL) that comprises metal layers, insulative material separating the metal layers from each other, and vias connecting the metal layers. Some of the metal layers may form a network to facilitate communications between various circuitry on a device side of the silicon. These features are described below. The portion 104 may include a final, or topmost, metal layer of the BEOL. Thus, the BEOL extends across both portions 102 and 104. Some of the metal layers may form a network to facilitate communications between various circuitry on the device side of the silicon and bond pads 306 on the portion 104.

The portion 104 includes a cavity 106. The cavity 106 has a floor 108 and multiple walls 110. As explained, the cavity 106 and floor 108 may cover the metal layer of portion 104, or it may be composed of the metal layer of portion 104. The cavity houses a patch antenna 112 (e.g., a 45-nm complementary metal oxide semiconductor (CMOS) process). The cavity 106 may have any suitable size and shape to accommodate the patch antenna 112. The patch antenna 112 includes a radiating portion 114 and a feed line 116 coupled to the radiating portion 114. The radiating portion 114 may be shaped and sized suitably to radiate energy (signals) outward and away from the portion 104. The feed line 116 extends horizontally from the radiating portion 114 as shown, and at a point distal form the radiating portion 114, the feed line 116 couples vertically downward to the BEOL in the portion 102. The feed line 116 supplies signals between the BEOL in the portion 102 and the radiating portion 114.

The floor 108 and/or walls 110 of the cavity 106 comprise metal that is coupled to a ground node in the die 100. In some examples, the floor 108 and/or walls 110 are separate from, but coupled to or in contact with, the portion 104, which itself may be the topmost metal layer. In other examples, the floor 108 and/or walls 110 are part of the portion 104 (e.g., the topmost metal layer). In some examples, the BEOL (which, as mentioned, will be described in greater detail below) of the portions 102 and 104 connects to a ground node on the silicon in the portion 102, and through a series of connections in the BEOL of the portion 102, the ground node extends from the silicon all the way up to the portion 104, the floor 108, and the walls 110. This forms one wall of the aforementioned ground structure. Additional, similar walls may be formed in the die 100, and these walls may couple to each other, similar to the manner in which the walls of a rectangular prism may couple to each other. The ground structure prevents or discourages the energy from radiating horizontally. FIG. 1B is a top-down view of the die 100, in accordance with various examples. FIG. 1C is a profile view of the die 100, in accordance with various examples.

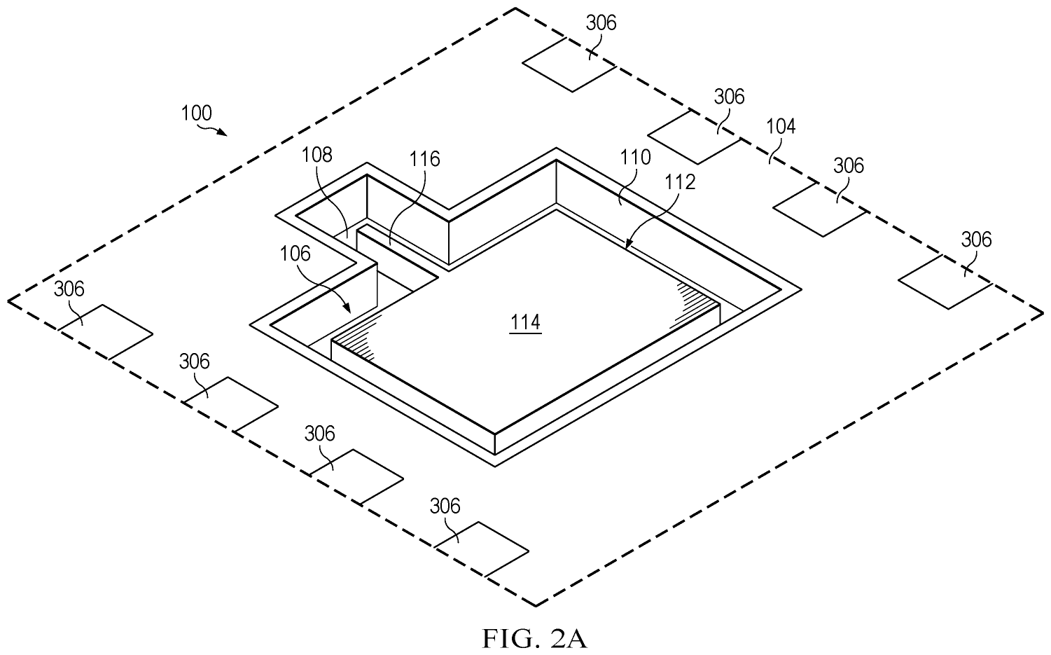

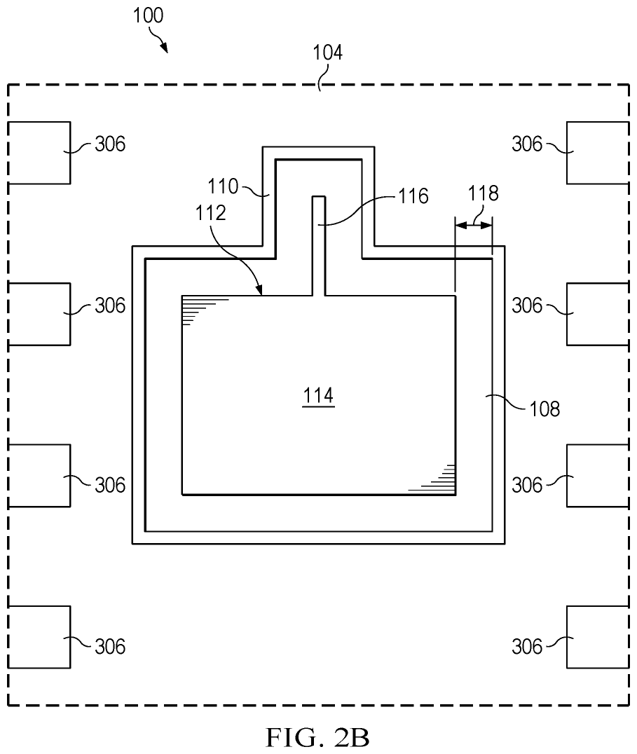

FIGS. 2A and 2B provide a more detailed view of the patch antenna 112 of FIGS. 1A-1C. Specifically, FIG. 2A is a perspective view of the patch antenna 112 configured to efficiently radiate wireless signals, in accordance with various examples. FIG. 2B is a top-down view of the patch antenna 112 configured to efficiently radiate wireless signals, in accordance with various examples. The cavity 106 has specific dimensions to facilitate radiation efficiency, and these dimensions are expressed relative to the patch antenna 112. The distance 118 between any point on a wall 110 and the closest point on the patch antenna 112 should be in a range from 20 microns to 30 microns, with a distance 118 below this range being disadvantageous because of increased coupling between the patch and the ground wall, and with a distance above this range being disadvantageous because it will increase the surface wave modes. The length of the patch antenna 112 is approximately half of the wavelength of the signal transmitted from or received by the patch antenna 112, and the width of the patch antenna 112 is tuned to produce a wide bandwidth, as desired. The patch antenna 112 receives communications from circuitry in the die 100 by way of the feed line 116 and radiates energy accordingly, and likewise, the patch antenna 112 receives communications wirelessly and provides corresponding signals to the feed line 116 for provision to the circuitry. In examples, the feed line 116 is a microstrip. In examples, the feed line 116 is a 50 ohm microstrip having a width of approximately 17 microns. In examples, the patch antenna 112 is configured to operate in the mmWave range (e.g., 30 GHz to 300 GHz). The circuitry communicating with the patch antenna 112 may be located on the silicon, in the BEOL of the die 100, on the floor 108, or any combination thereof.

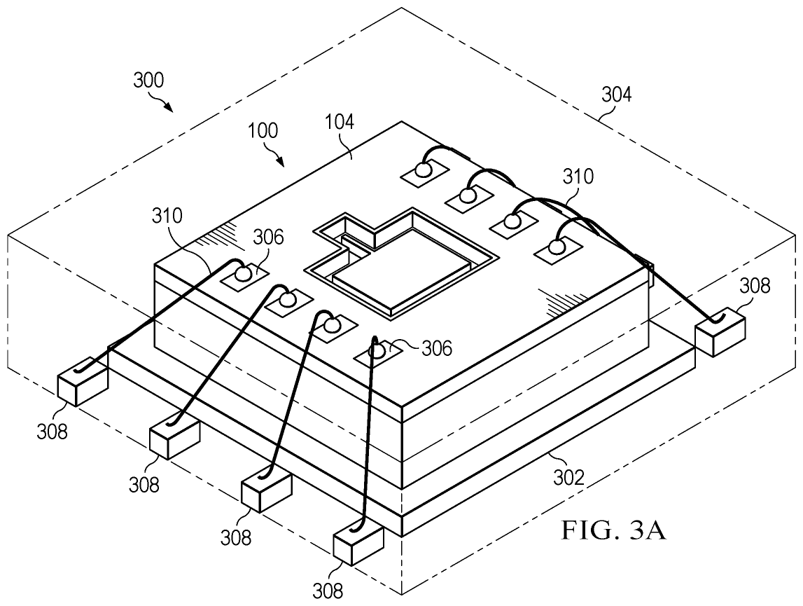

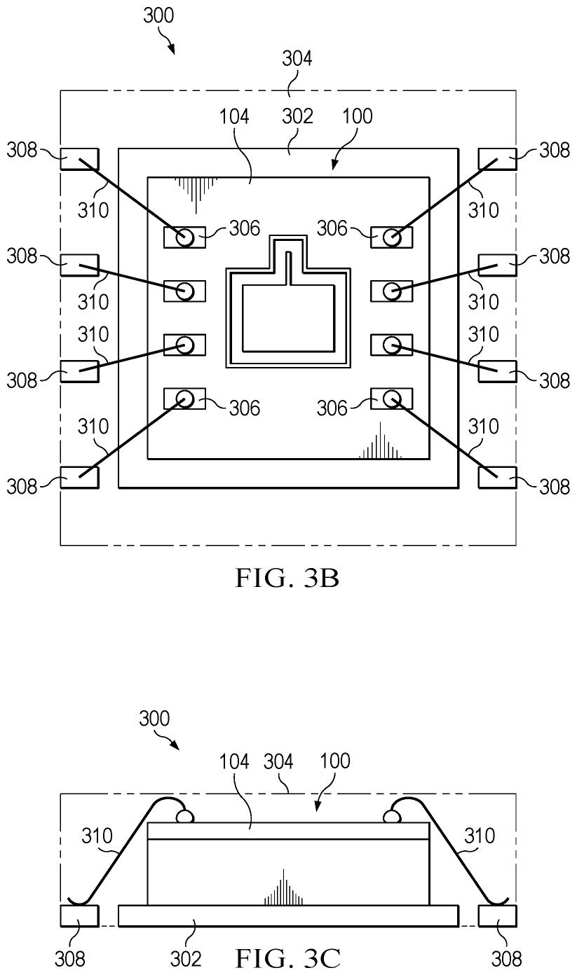

FIG. 3A is a perspective view of a patch antenna semiconductor package 300 configured to efficiently radiate wireless signals, in accordance with various examples. In examples, the package 300 includes a substrate 302 on which the semiconductor die 100 is placed. For instance, the die 100 may be placed on the substrate 302 by way of a die attach film. A mold compound 304 may be applied to cover the die 100 and the substrate 302. Circuitry within the die 100 (e.g., circuitry formed on silicon) may communicate with electronics outside of the package 300 by wirebonds 310 that couple the bond pads 306 to conductive terminals 308. The conductive terminals 308 are exposed to the exterior of the mold compound 304, thus enabling the conductive terminals 308 to be coupled (e.g., soldered) to metal contacts on a printed circuit board or other device. FIG. 3B is a top-down view of the structure of FIG. 3A, and FIG. 3C is a profile view of the structure of FIG. 3A.

The mold compound 304 has specific properties that promote radiation efficiency. The thickness of the mold compound 304 as measured from the top surface of the patch antenna 112 to the top surface of the mold compound 304 is approximately one fourth of the wavelength of the signals that the patch antenna 112 is configured to radiate. Experimental data indicates that a mold compound 304 having this thickness (i.e., one fourth of the wavelength of the signals that the patch antenna 112 is configured to radiate) provides a 20% improvement in radiation efficiency compared to mold compounds lacking this specific thickness. Thus, this mold compound thickness is critical to achieving superior radiation efficiency improvements of approximately 20%, and mold compounds that are thinner or thicker than this thickness will produce inferior radiation efficiency results. In addition to the thickness of the mold compound 304, the composition of the mold compound 304 affects radiation efficiency. Table 1 provides experimental data showing the critical material properties of the mold compound 304 to achieve superior radiation efficiency, in particular with respect to the relative permittivity and the loss tangent of the mold compound 304. Materials 1-5 listed in Table 1 are epoxy-based mold compounds comprising silica filler particles.

TABLE 1
Experimental data showing critical material properties of the
mold compound 304 to achieve superior radiation efficiency.

| Material | Relative permittivity | Loss tangent |
|---|---|---|
| Material 1 | 2.36 | 0.013 |
| Material 2 | 3.4 | 0.0025 |
| Material 3 | 3.5 | 0.013 |
| Material 4 | 3.55 | 0.0095 |
| Material 5 | 3.86 | 0.011 |

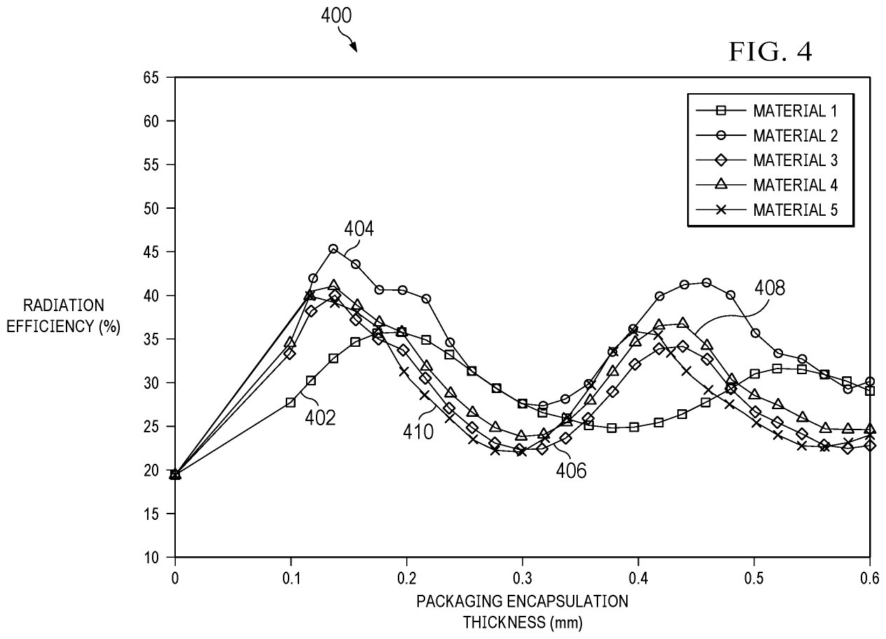

FIG. 4 depicts the performance of Materials 1-5 of Table 1. Specifically, FIG. 4 is a graph depicting radiation efficiency as a function of mold compound 304 thickness at a frequency of 300 GHz. The thickness of the mold compound 304 is defined as the distance from the top surface of the patch antenna 112 to the top surface of the mold compound 304. The frequency of 300 GHz is the frequency at which the patch antenna 112 radiates energy. The behaviors depicted in FIG. 4 hold for a range of frequencies in the mmWave band, and not merely for 300 GHz. In graph 400 of FIG. 4, curve 402 depicts the performance of Material 1; curve 404 depicts the performance of Material 2; curve 406 depicts the performance of Material 3; curve 408 depicts the performance of Material 4; and curve 410 depicts the performance of Material 5. The lower the loss tangent of a given material, the higher the radiation efficiency of that material. This is true for electromagnetic waves propagating through any dielectric medium. However, the radiation efficiency of materials having different permittivities is not as readily predictable. As described below, experiments indicate that the specific process used to form back-end-of-line (BEOL) metal layers of the semiconductor die in a given package (e.g., radio frequency (RF) CMOS process), the properties of the inter-metal dielectric materials used in the BEOL metal layers, and the manner in which these materials interact with the permittivities of the mold compound 304 contribute to the radiation efficiency of the mold compound 304. Mold compound 304 thickness is depicted on the x-axis of graph 400, while the y-axis depicts radiation efficiency. Curve 402 shows that Material 1 performs particularly poorly relative to Materials 2-5 in the 0.0 mm-0.18 mm mold compound thickness range, and that it performs relatively well in the 0.2 mm-0.3 mm and 0.5 mm-0.6 mm mold compound thickness ranges. Curve 404 shows that Material 2 consistently outperforms Materials 1 and 3-5, or at the very least, Material 2 is not outperformed by any of Materials 1 and 3-5. Thus, Material 2 is a superior candidate for improving radiation efficiency. Curve 406 shows that Material 3 is generally outperformed by one or more of Materials 1, 2, 4, and 5 in most mold compound thickness ranges, and thus Material 3 is not a superior candidate for inclusion in mold compound 304. Curve 408 shows that Material 4 outperforms most of the materials in the 1.2 mm-1.8 mm and 0.4 mm-0.46 mm mold compound thickness ranges, but Material 4 does not outperform Material 2 at any thickness. Finally, curve 410 shows that Material 5 is generally one of the poorest performers among Materials 1-5. Comparing the relative performances of Materials 1-5, Material 2 is clearly superior to the remaining materials, and Material 1 is also superior to Materials 3-5 and comparable to Material 2 in the mold compound thickness ranges of 0.2 mm-0.3 mm and 0.5 mm-0.6 mm.

Based on the results shown in FIG. 4, when Material 2 is used, the thickness of mold compound 304 may range from 0.13 mm to 0.25 mm or from 0.4 mm to 0.53 mm for optimal performance. Based on the results shown in FIG. 4, when Material 3 is used, the thickness of mold compound 304 may range from 0 mm to 0.16 mm or from 0.16 mm to 0.3 mm or from 0.425 mm to for optimal performance.

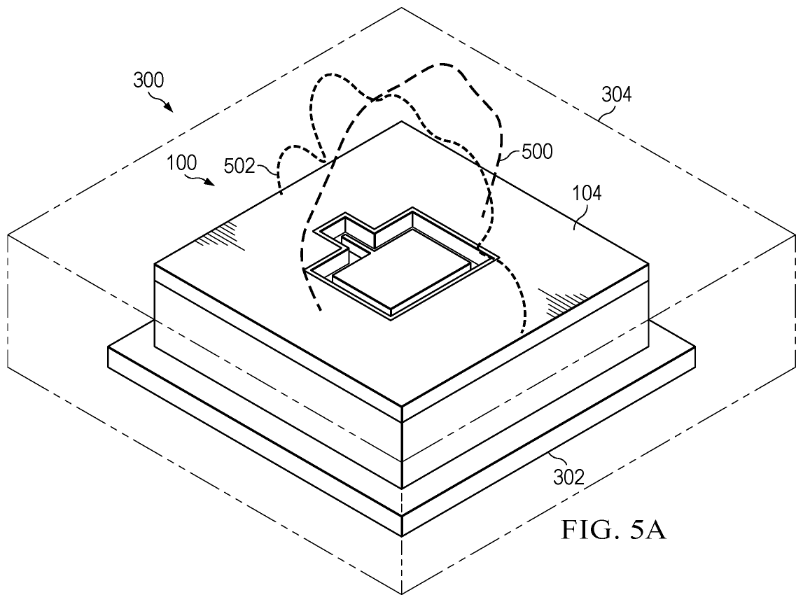

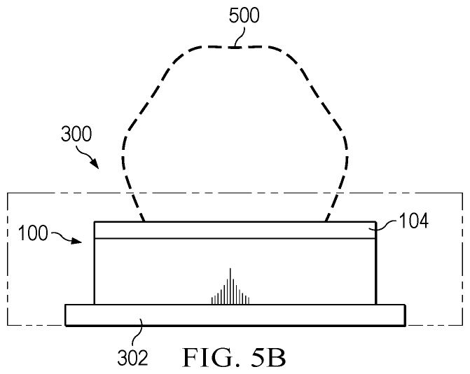

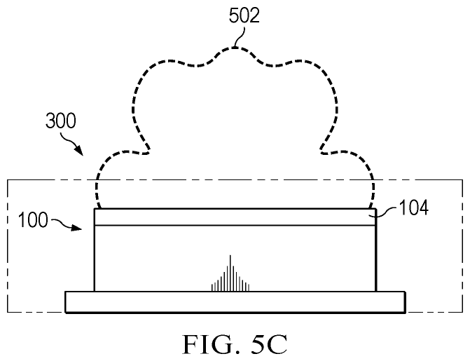

FIG. 5A is a perspective view of the semiconductor package 300 and the radiation gain patterns of efficiently radiated wireless signals, in accordance with various examples. In particular, FIG. 5A shows a radiation gain (radiation) pattern in the Φ=0° plane 500 and in the Φ=90° plane 502. As shown, the radiation patterns are directional, meaning that they primarily extend from the patch antenna 112 in a direction that is normal to the patch antenna 112. The radiation patterns assume a mold compound 304 of Material 3 (Table 1), a thickness of 140 microns, and an operating frequency of 300 GHz (although similar radiation patterns will result from other operation frequencies in the mmWave range). FIGS. 5B and 5C provide alternate profile views of the radiation patterns shown in FIG. 5A, in accordance with various examples.

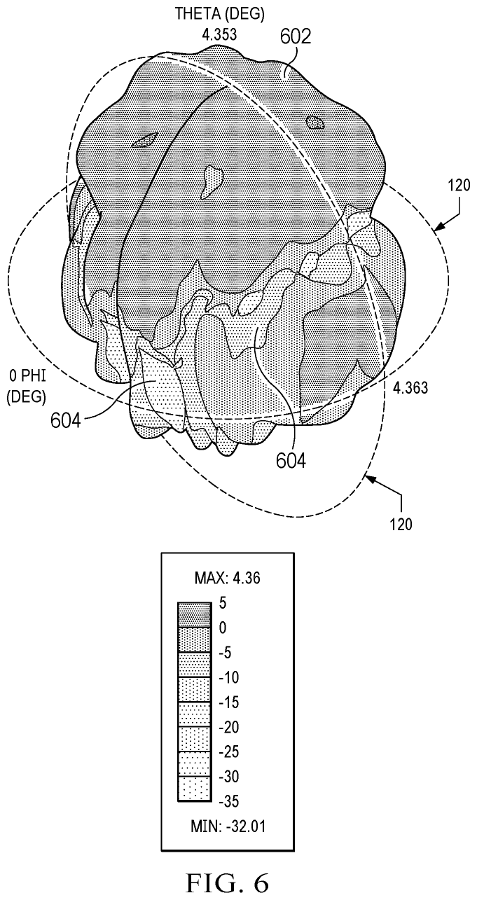

FIG. 6 provides another depiction of the gain (radiation) pattern provided by the semiconductor package 300. The illustration of FIG. 6 is a 3-d polar plot of the gain at 300 GHz, although similar radiation patterns will result from other operation frequencies in the mmWave frequency range. FIG. 6 assumes a mold compound 304 of Material 3 (Table 1) and a thickness of 140 microns. As shown in FIG. 6, the peak gain is approximately 4.363 dB. Importantly, the peak gain levels are present in the normal direction relative to the patch antenna 112 (FIG. 5A), for example along a vertical axis extending from the patch antenna 112 in a normal direction as numerals 602 indicate, and the minimum gain levels are present in directions perpendicular to such a vertical axis, as numerals 604 indicate.

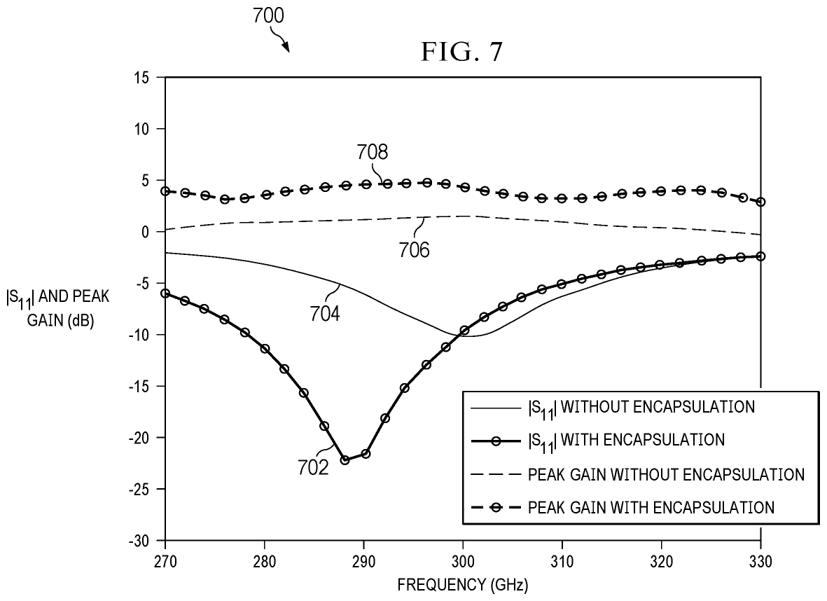

FIG. 7 is a graph 700 depicting gains and return losses (in dB) as a function of the frequency of a signal (in GHz) radiated by a patch antenna semiconductor package 300, in accordance with various examples. Graph 700 includes curves 702 (return losses with the mold compound 304 present in the semiconductor package 300), 704 (return losses without the mold compound 304 present in the semiconductor package 300), 706 (peak gain without the mold compound 304 present in the semiconductor package 300), and 708 (peak gain with the mold compound 304 present in the semiconductor package 300). As curves 702 and 704 indicate, across a sweep of operating frequencies from 270 GHz to 330 GHz, the presence of the mold compound 304 in the package 300 results in wider impedance bandwidth performance. As curves 706 and 708 indicate, across the sweep of operating frequencies from 270 GHz to 330 GHz, the presence of the mold compound 304 in the package 300 consistently produces superior gain compared to the absence of the mold compound 304 in the package 300.

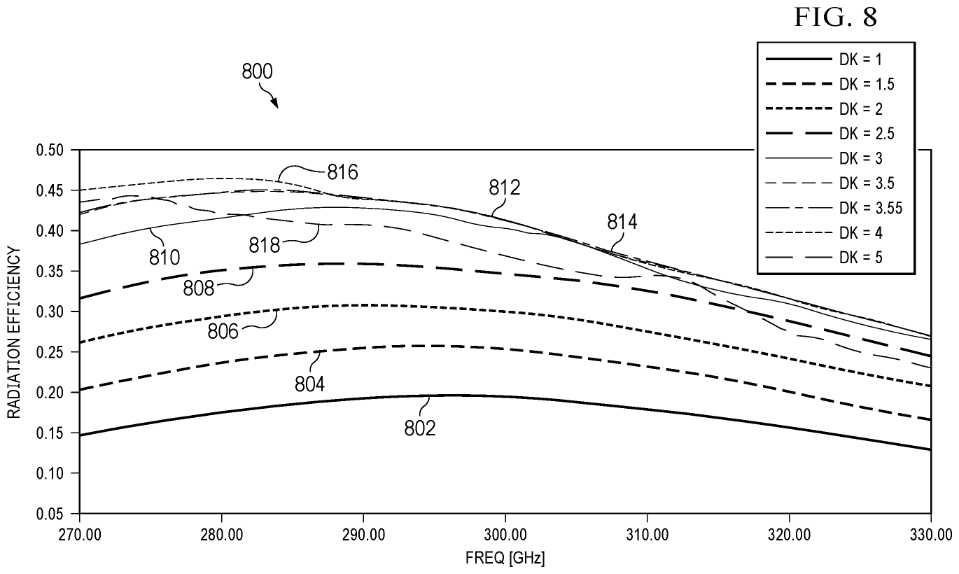

FIG. 8 is a graph 800 depicting radiation efficiency as a function of signal frequency for a range of different mold compound relative permittivity values, in accordance with various examples. The graph 800 includes curves 802, 804, 806, 808, 810, 812, 814, 816, and 818 for relative permittivity values 1, 1.5, 2, 2.5, 3, 3.5, 3.55, 4, and 5, respectively. The mold compound loss tangent is held constant at 0.013 to facilitate an even-handed comparison of the range of relative permittivity values. As shown, for the frequency sweep range of 270 GHz to 330 GHz, the curve 814 (relative permittivity of 3.55) has the highest area under the curve (AUC) and thus the best overall performance among the various mold compound relative permittivities.

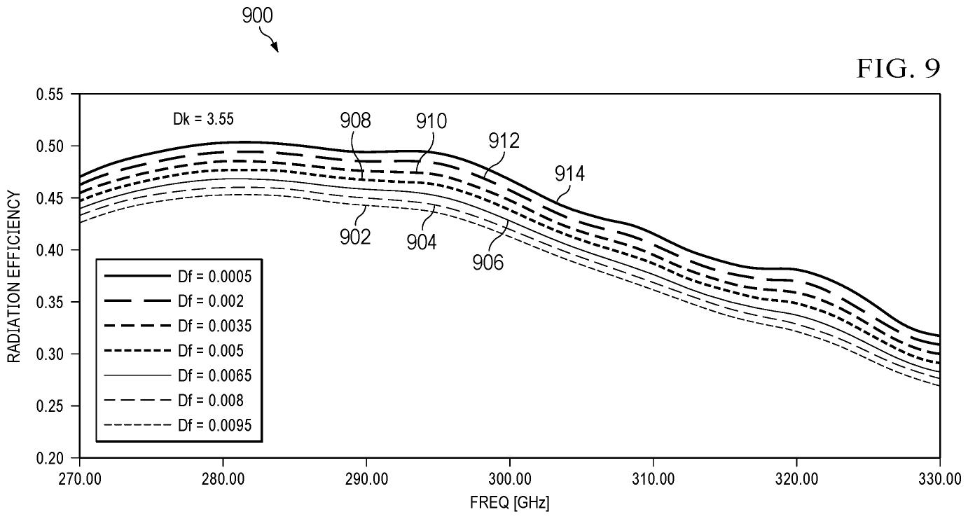

FIG. 9 is a graph 900 depicting radiation efficiency as a function of signal frequency for a range of different mold compound loss tangent values, in accordance with various examples. The graph 900 includes curves 902, 904, 906, 908, 910, 912, and 914 for loss tangent values 0.0095, 0.0065, 0.005, 0.0035, 0.002, and 0.0005, respectively. The mold compound relative permittivity is held constant at 3.55 to facilitate an even-handed comparison of the range of loss tangent values. As shown, for the frequency sweep range of 270 GHz to 330 GHz, the curve representing the lowest loss tangent (in this case, curve 914 corresponding to a loss tangent of produces the greatest radiation efficiency. These experimental data are useful in determining the mold compound relative permittivity and loss tangent value combinations with the greatest radiation efficiencies, as shown in Table 1.

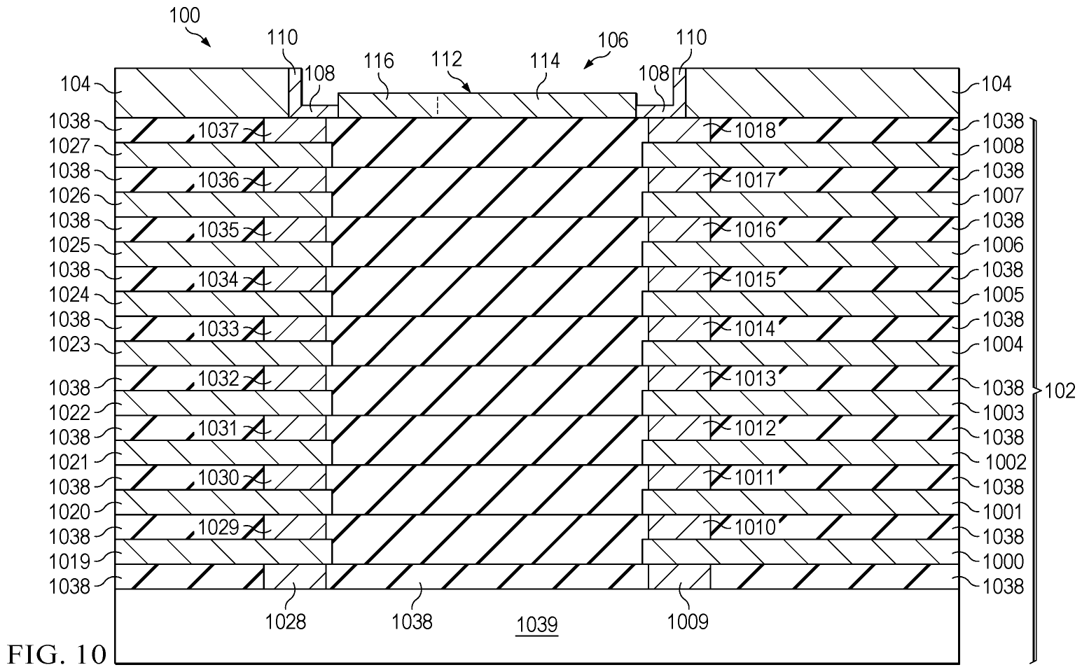

FIG. 10 is a profile, cross-sectional view of the patch antenna semiconductor die 100 configured to efficiently radiate wireless signals, in accordance with various examples. The die 100 includes a silicon substrate 1039 (also referred to herein as the silicon 1039, although other types of semiconductors may be substituted for silicon) that has a device side including circuitry and a non-device side opposite the device side. The device side faces upward, toward the remaining structures of the die 100. The die 100 includes multiple metal layers 1000-1008. The die 100 also includes the portion 104, which is a top-most metal layer. Metal layer 1000 is coupled to the silicon 1039 (for example, to a ground node on the device side of the silicon 1039) by way of a via 1009. Metal layers 1001-1008 are coupled to metal layers 1000-1007, respectively, by way of vias 1010-1017, respectively. Via 1018 couples the metal layer 1008 to the portion 104 (e.g., the topmost metal layer of the BEOL) and/or to the floor 108 and/or walls 110. Metal layers 1000-1008, vias 1009-1018, the portion 102, and the floor 108 and walls 110 of the cavity 106 form a ground wall, as described above. The die 100 also includes metal layers 1019-1027 and vias 1028-1037. Metal layers 1020-1027 couple to metal layers 1019-1026, respectively, by way of vias 1029-1036, respectively. In examples, via 1037 couples the metal layer 1027 to the portion 104 (e.g., the topmost metal layer of the BEOL) and/or to the floor 108 and/or the walls 110. The view of FIG. 10 thus depicts two ground walls. The die 100 includes two additional ground walls that are not visible in the planar view of FIG. 10. Together, these four ground walls form the ground structure described herein. The space between the ground walls is in vertical alignment with the patch antenna 112. Thus, during operation, energy radiated by the patch antenna 112 propagates vertically, and the ground structure composed of the aforementioned ground walls prevents or at least mitigates radiation in the horizontal/lateral direction. This imparts directionality to the energy radiation, causing more energy to be radiated vertically and specifically upward and away from the die 100, thereby increasing radiation efficiency. Alternate configurations are contemplated and included in the scope of this disclosure. An insulative material 1038 (e.g., polyimide) covers the various metal layers and vias within the die 100 as shown.

In FIG. 10, the metal layers in the portion 102 are depicted as having a combined thickness greater than that of the silicon 1039. However, in examples, the thickness of the silicon 1039 may substantially exceed the combined thickness of the metal layers in the portion 102.

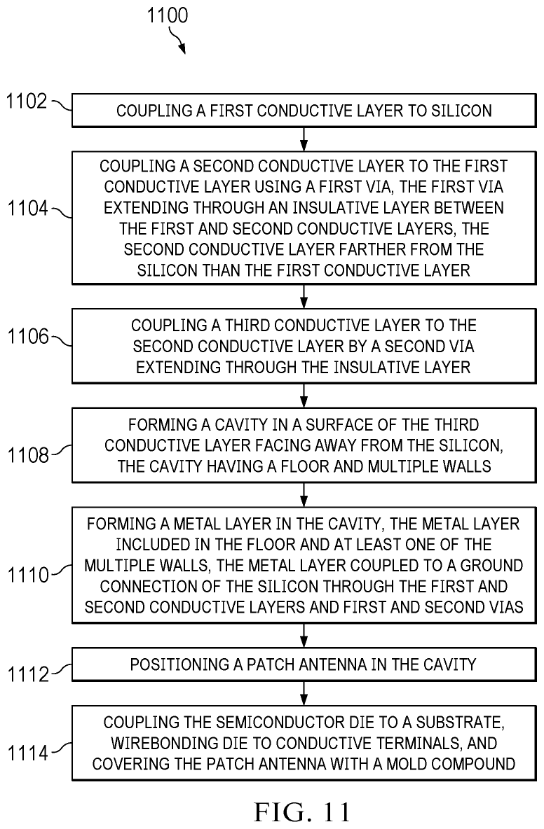

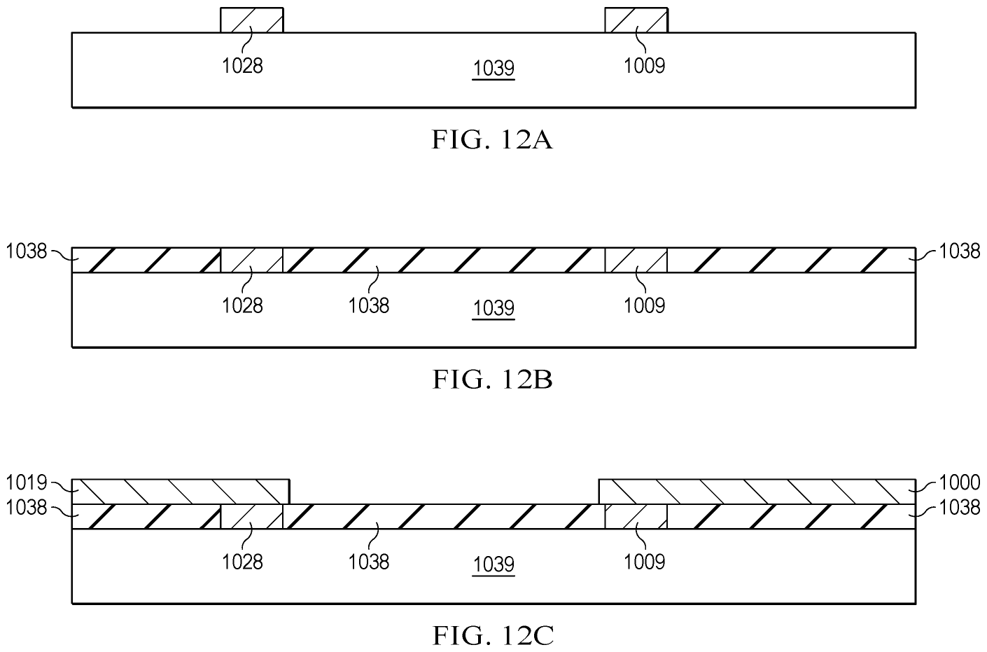

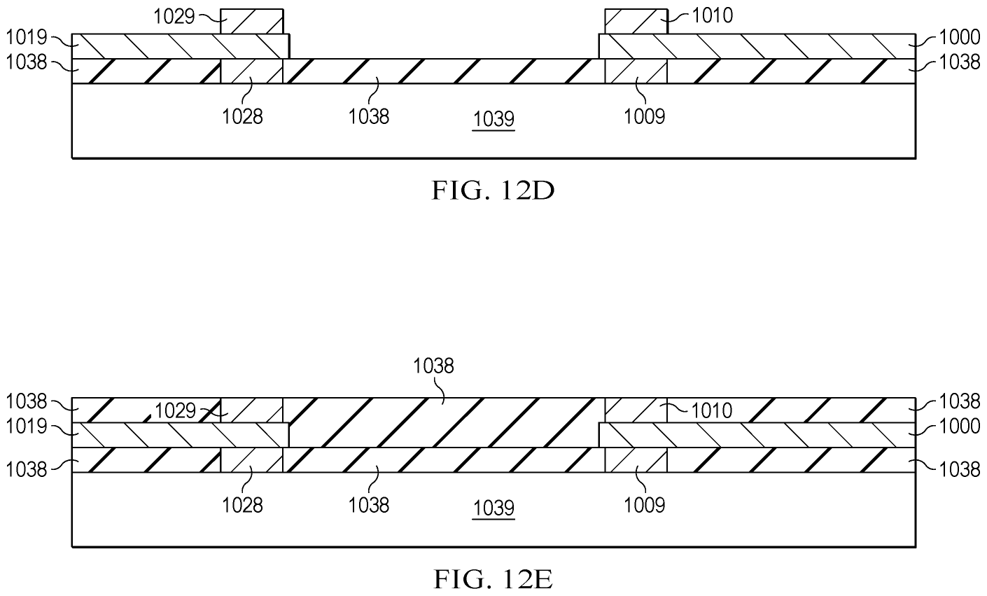

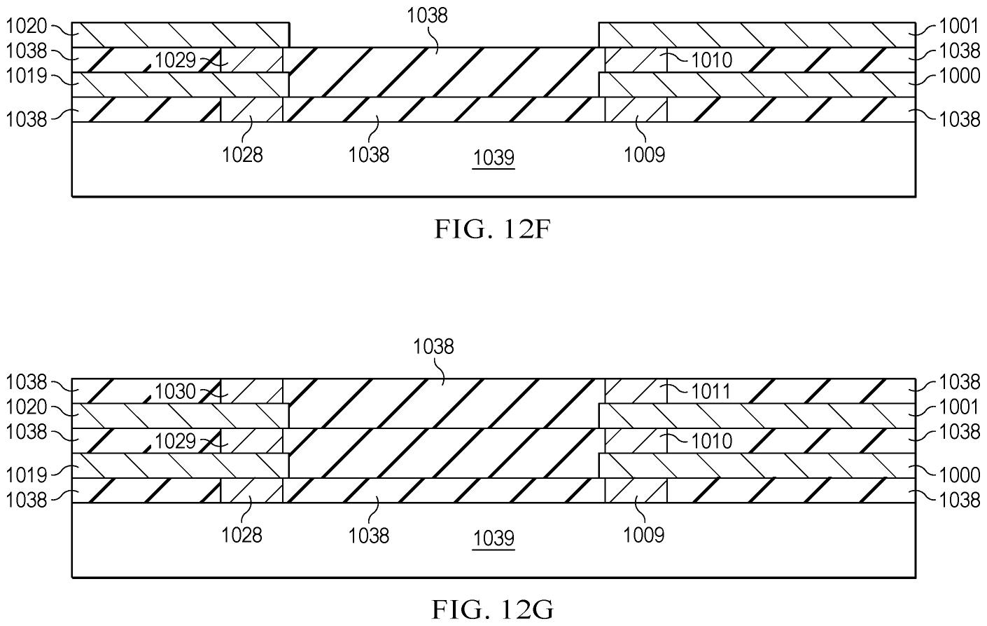

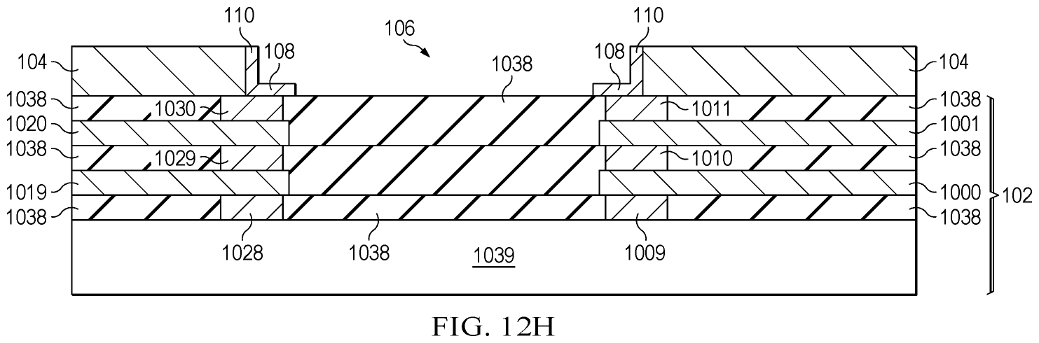

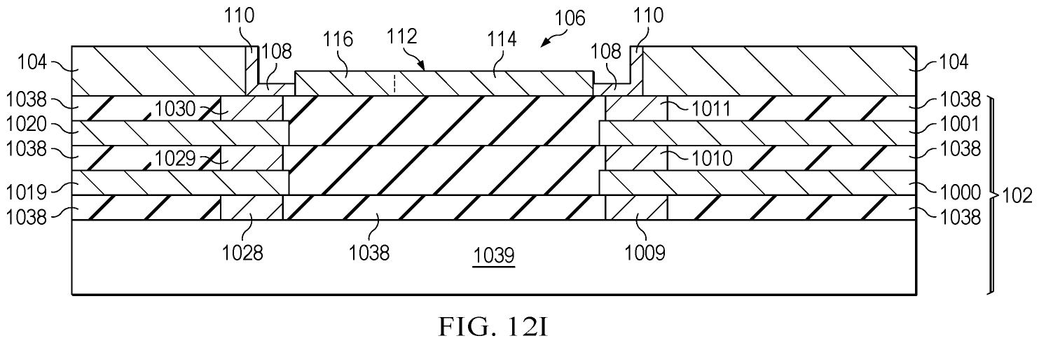

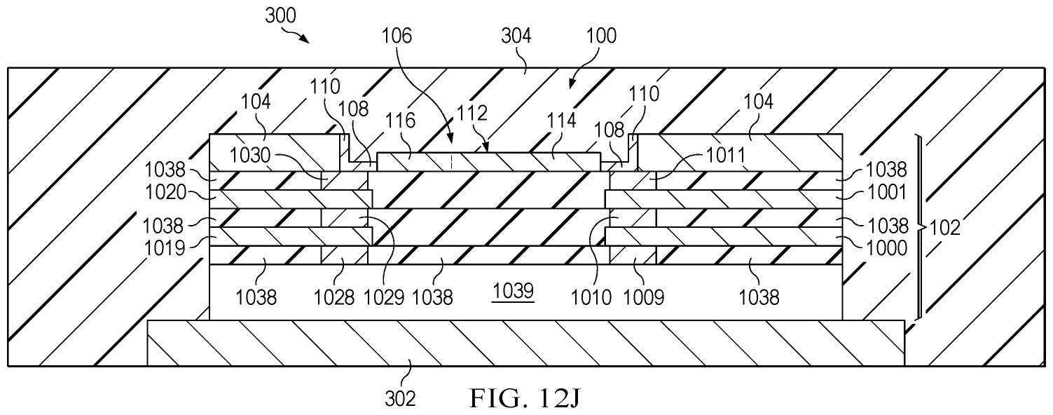

FIG. 11 is a flow diagram of a method 1100 for manufacturing a patch antenna semiconductor package, such as the package 300, in accordance with various examples. FIGS. 12A-12J are a process flow of a method for manufacturing a patch antenna semiconductor package, such as the package 300, in accordance with various examples. Accordingly, FIGS. 11 and 12A-12J are now described in parallel. The method 1100 begins with coupling a first conductive layer to a silicon substrate (1102). FIG. 12A shows the silicon 1039 and vias 1028 and 1009 formed on a device side of the silicon 1039. The vias 1028 and 1009, as well as the remaining vias and conductive/metal layers described herein, may be formed by any suitable technique, such as a plating technique using appropriate seed layers and/or other materials. FIG. 12B shows the application of insulative material 1038 to the silicon 1039 and the vias 1028 and 1009. FIG. 12C shows the formation of conductive layers 1019 and 1000 coupled to the vias 1028 and 1009, respectively.

The method 1100 comprises coupling a second conductive layer to the first conductive layer using a first via, the first via extending through an insulative layer between the first and second conductive layers, the second conductive layer farther from the silicon than the first conductive layer (1104). FIG. 12D shows the formation of vias 1029 and 1010 on conductive layers 1019 and 1000, respectively. FIG. 12E shows the application of insulative material 1038 to the vias 1029 and 1010 and the conductive layers 1019 and 1000. FIG. 12F shows the formation of conductive layers 1020 and 1001 coupled to the vias 1029 and 1010, respectively.

The method 1100 also comprises coupling a third conductive layer to the second conductive layer by a second via extending through the insulative material (1106). The method 1100 further includes forming a cavity in a surface of the third conductive layer facing away from the silicon, the cavity having a floor and multiple walls (1108). The method 1100 includes forming a metal layer in the cavity, the metal layer included in the floor and at least one of the walls of the cavity (e.g., the floor and the at least one wall are composed of the metal layer), the metal layer coupled to a ground connection of the silicon through the first and second conductive layers and the first and second vias (1110). FIG. 12G shows the formation of vias 1030 and 1011, along with application of additional insulative material 1038. FIG. 12H shows the formation of the third conductive layer 104 and the cavity 106 in a top surface of the third conductive layer 104. In examples, the cavity is formed in the third conductive layer 104 through appropriate photolithography and plating techniques. In some examples, a metal layer is formed on the floor 108 and one or more walls 110 of the cavity 106, and the metal layer on the floor 108 contacts the via 1011 and the via 1030. In some examples, the floor 108 and walls 110 are part of the third conductive layer 104, and the vias 1030, 1011 are coupled to the third conductive layer 104, the floor 108, and/or the walls 110.

The method 1100 includes positioning a patch antenna in the cavity (1112). FIG. 12I shows the patch antenna 112 positioned in the cavity 106. In examples, the patch antenna 112 is part of a metal layer (not expressly shown) in the portion 102. In addition to coupling to circuitry on the silicon 1039, the feed line 116 may also be coupled to circuitry formed in the metal layers of the portion 102, circuitry formed on the floor 108, or a combination thereof. The method 1100 includes coupling the semiconductor die to a substrate (e.g., a printed circuit board), wirebonding the bond pads on the die to conductive terminals, and covering the patch antenna, as well as the various conductive and insulative layers, the cavity, the conductive terminals, and the substrate, with a mold compound (1114). FIG. 12J shows an example package 300 including the substrate 302 and the mold compound 304 covering the various components of the package 300. Although the package 300 in FIG. 12J has a different number of conductive layers and vias than the die 100 in FIG. 10, any suitable number of conductive layers and/or vias may be useful.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

Uses of the term “ground” and variations thereof in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a semiconductor substrate including a device side having circuitry formed therein;
a conductive layer positioned above the semiconductor substrate;
a patch antenna coupled to the conductive layer and to the device side of the semiconductor substrate; and
a mold compound covering the patch antenna, the mold compound having a relative permittivity ranging from 3.4 to 3.5 and a loss tangent ranging from 0.0025 to 0.013.

2. The package of claim 1, wherein the mold compound has a relative permittivity of approximately 3.4 and a loss tangent of approximately 0.0025.

3. The package of claim 2, wherein the mold compound has a vertical thickness ranging from mm to 0.25 mm.

4. The package of claim 2, wherein the mold compound has a vertical thickness ranging from mm to 0.53 mm.

5. The package of claim 1, wherein the mold compound has a relative permittivity of approximately 3.5 and a loss tangent of approximately 0.013.

6. The package of claim 5, wherein the mold compound has a vertical thickness ranging from mm to 0.16 mm.

7. The package of claim 5, wherein the mold compound has a vertical thickness ranging from mm to 0.3 mm.

8. The package of claim 5, wherein the mold compound has a vertical thickness ranging from mm to 0.56 mm.

9. The package of claim 1, wherein the mold compound has a vertical thickness of one-quarter of a wavelength of a signal that the patch antenna is configured to radiate.

10. A semiconductor package, comprising:
a semiconductor substrate including a device side having circuitry formed therein;
multiple conductive layers positioned above the semiconductor substrate, each of the multiple conductive layers coupled to another one of the multiple conductive layers by a different via, the multiple conductive layers including a top conductive layer positioned farthest from the semiconductor substrate;
a ground member in a cavity of the top conductive layer, the ground member coupled to a ground connection in the circuitry by way of the vias;
a patch antenna in the cavity; and
a mold compound covering the patch antenna, the mold compound having a relative permittivity ranging from 3.4 to 3.5 and a thickness from the patch antenna to a top surface of the mold compound that is approximately one-fourth of a wavelength of a wireless signal to be emitted by the patch antenna.

11. The package of claim 10, wherein the ground member is included in a floor of the cavity.

12. The package of claim 10, wherein the ground member covers multiple walls of the cavity.

13. The package of claim 10, wherein the mold compound has a relative permittivity of approximately 3.4.

14. The package of claim 10, wherein the mold compound has a loss tangent of approximately 0.0025.

15. A semiconductor package, comprising:
a semiconductor substrate including a device side having circuitry formed therein;
multiple conductive layers positioned above the semiconductor substrate, each of the multiple conductive layers coupled to another one of the multiple conductive layers by a different via, the multiple conductive layers including a top conductive layer positioned farthest from the semiconductor substrate;
a ground member in a cavity of the top conductive layer, the ground member coupled to a ground connection in the circuitry by way of the vias, the ground member included in a floor of the cavity and a wall of the cavity;
a patch antenna in the cavity; and
a mold compound covering the patch antenna, the mold compound having a relative permittivity ranging from 3.4 to 3.5 and a loss tangent ranging from 0.0025 to 0.013.

16. The package of claim 15, wherein the ground member covers all walls of the cavity.

17. The package of claim 16, wherein a distance between an edge of the patch antenna and a closest wall of the cavity is between 20 and 30 microns.

18. The package of claim 15, wherein the mold compound has a relative permittivity of approximately 3.4 and a loss tangent of approximately 0.0025.

19. The package of claim 18, wherein the mold compound has a vertical thickness ranging from mm to 0.25 mm.

20. The package of claim 18, wherein the mold compound has a relative permittivity of approximately 3.5 and a loss tangent of approximately 0.013.

21. A method for manufacturing a semiconductor package, comprising:
coupling a first conductive layer to a semiconductor substrate;
coupling a second conductive layer to the first conductive layer using a via, the via extending through an insulative layer between the first and second conductive layers, the second conductive layer farther from the semiconductor substrate than the first conductive layer;
forming a cavity in a surface of the second conductive layer facing away from the semiconductor substrate, the cavity having a metal floor and multiple metal walls, the floor and multiple walls coupled to a ground connection of the semiconductor substrate through the via;
positioning a patch antenna in the cavity; and
covering the patch antenna with a mold compound.

22. The method of claim 21, wherein the mold compound has a relative permittivity ranging from 3.4 to 3.5.

23. The method of claim 21, wherein the mold compound has a loss tangent of approximately 0.0025.

24. The method of claim 21, wherein the mold compound has a loss tangent of approximately 0.013.
